(19) United States
(12) Patent Application Publication
(10) Pub. No.: US 2026/0265581 A1
(43) Pub. Date: Sep. 10, 2026

(54) TRANSFER FILM FOR HIGH-SPEED TRANSFER PROCESS AND TRANSFER METHOD USING SAME

(71) Applicants: KOREA INSTITUTE OF MACHINERY & MATERIALS, Daejeon (KR); CENTER FOR ADVANCED META-MATERIALS, Daejeon (KR)

(72) Inventors: Chan KIM, Daejeon (KR); Kwangseop KIM, Daejeon (KR); Jae-Hyun KIM, Daejeon (KR); Kyung-Sik KIM, Daejeon (KR); Min-Ah YOON, Daejeon (KR); Hak Joo LEE, Daejeon (KR)

(21) Appl. No.: 19/164,723

(22) PCT Filed: Oct. 31, 2023
(86) PCT No.: PCT/KR2023/017060

§ 371 Date: Sep. 12, 2025

(30) Foreign Application Priority Data
Mar. 13, 2023 (KR) 10-2023-0032746

(51) Int. Cl. C09J 7/29; C09J 7/38

(52) U.S. Cl. CPC C09J 7/29; C09J 7/38

(57) ABSTRACT

The present disclosure relates to a transfer film for high-speed transfer process and a transfer method using the same, and the transfer film for high-speed transfer film according to the present disclosure includes a first adhesive layer formed of a viscoelastic material so that a device is adhered thereto, a support layer supporting the first adhesive layer, a second adhesive layer formed of a viscoelastic material so that the support layer is adhered thereto, and a rigidity reinforcement layer reinforcing a rigidity of the film and supporting the second adhesive layer, wherein, when a placing process is performed after performing a picking process, the placing process is performed after the rigidity reinforcement layer is removed so as to weaken the rigidity of the film.

### TECHNICAL FIELD

The present disclosure relates to a transfer film for high-speed transfer process and a transfer method using the same, and in particular, to a transfer film for high-speed transfer process, which is capable of transferring micro-devices on a target substrate at a high speed, and a transfer method using the transfer film.

### BACKGROUND ART

Recently, the importance of micro/nano technologies has been increasing due to technical development in electronic appliances. Most of electronic appliances incorporating micro/nano technologies have thin-film type micro-devices (e.g., mini-LED, micro-LED, thin-film solar cell) provided therein.

Semiconductor processes, flexible electronic appliance processes, display processes, MEMS processes, LED processes, solar cell processes, etc. require a transfer process for transferring thin-film type devices onto a target substrate.

With respect to thick devices, a transfer process may be performed by using a vacuum chuck technique or an electrostatic chuck technique, which may be difficult to be applied to thin-film devices because they are vulnerable. Accordingly, a transfer process using a transfer film has been widely used with respect to a thin film device.

The transfer process using the transfer film includes a picking process for moving devices arranged on a base substrate (base film) to a transfer film, and a placing process for moving the devices on the transfer film to a target substrate, and the devices arranged on the base substrate may be moved to and arranged on the target substrate by the transfer film.

According to the prior art, a transfer film is formed in a form in which an adhesive layer including a viscoelastic material is formed on a base film, that is, a support layer, and when performing a placing process in which the transfer film is detached from the target substrate after bringing the transfer film into contact with the target substrate, an adhesive force of the adhesive layer increases as a speed of detaching the transfer film increases, that is, a speed-dependent characteristic is shown. That is, micro-devices are easily detached from the transfer film only when the transfer film is slowly detached. Therefore, a micro-device transfer process using the transfer film inevitably has a reduced speed in the placing process, and thereby decreasing productivity.

### DISCLOSURE OF INVENTION

### Technical Problem

Therefore, to address the above issues, the present disclosure provides a transfer film for high-speed transfer process and a transfer method using the transfer film, which may improve productivity because an adhesive force between a micro-device and the transfer film is not much increased even with increased placing speed by reducing a speed-dependent adhesive characteristic of an adhesive layer on the transfer film between a picking process and a placing process.

The objectives to be solved by the present disclosure are not limited to the objectives described above, and other objectives not described would be clearly understood by those skilled in the art from the description below.

### Solution to Problem

An embodiment of the present disclosure provides a transfer film for a high-speed transfer process, the transfer film includes a first adhesive layer formed of a viscoelastic material so that a device is adhered thereto, a support layer supporting the first adhesive layer, a second adhesive layer formed of a viscoelastic material so that the support layer is adhered thereto, and a rigidity reinforcement layer reinforcing a rigidity of the transfer film and supporting the second adhesive layer, wherein, when a placing process is performed after performing a picking process, the placing process is performed after the rigidity reinforcement layer is removed so as to weaken the rigidity of the transfer film.

### Advantageous Effects of Invention

According to a transfer film for high-speed transfer process and a transfer method using the transfer film of the present disclosure, a speed-dependent adhesive characteristic of an adhesive layer on the transfer film is reduced between a picking process and a placing process, and thus, the adhesive force between a micro-device and the transfer film is not much increased even when a placing speed increases, thereby improving productivity.

### BRIEF DESCRIPTION OF DRAWINGS

FIG. 1A and FIG. 1B are diagrams showing a transfer film for a high-speed transfer process, according to an embodiment of the present disclosure.

FIG. 2 is a diagram showing a modified example of FIG. 1A and FIG. 1B.

FIG. 3 is a diagram showing another modified example of FIG. 1A and FIG. 1B.

FIG. 4 is a graph showing a variation in an adhesive force depending on a placing speed, in a transfer film for high-speed transfer process according to the present disclosure and a transfer film according to the prior art.

FIG. 5A and FIG. 5B are diagrams showing a transfer film for high-speed transfer film, according to another embodiment of the present disclosure.

FIGS. 6A to 8B are diagrams showing modified examples of FIG. 5A and FIG. 5B.

FIG. 9 is a diagram showing results of measuring an adhesive force according to a placing speed, with respect to a rigidity of a speed-dependent adhesive characteristic control layer in FIG. 5A and FIG. 5B.

FIG. 10 is a diagram showing a transfer film for high-speed transfer process, according to another embodiment of the present disclosure.

### BEST MODE FOR CARRYING OUT THE INVENTION

The above purpose may be achieved by, according to the present disclosure, a transfer film for a high-speed transfer process, including a first adhesive layer formed of a viscoelastic material so that a device is adhered thereto, a support layer supporting the first adhesive layer, a second adhesive layer formed of a viscoelastic material so that the support layer is adhered thereto, and a rigidity reinforcement layer reinforcing a rigidity of the transfer film and supporting the second adhesive layer, wherein, when a placing process is performed after performing a picking process, the placing process is performed after the rigidity reinforcement layer is removed so as to weaken the rigidity of the transfer film.

In some embodiments, the rigidity reinforcement layer may be formed in multi-layers.

In some embodiments, the rigidity reinforcement layer may be formed of a material having a rigidity greater than a rigidity of the support layer.

In some embodiments, the rigidity reinforcement layer may be partially removable.

In some embodiments, the transfer film may further include a speed-dependent adhesive characteristic control layer which is formed above one surface of the support layer, which faces the second adhesive layer of the support layer, and controls a characteristic that an adhesive force of the first adhesive layer changes according to a placing speed.

In some embodiments, the speed-dependent adhesive characteristic control layer may be formed of a material having a rigidity less than the rigidity of the support layer.

In some embodiments, the speed-dependent adhesive characteristic control layer may be formed of a material having rigidity that varies depending on external physical changes.

In some embodiments, the speed-dependent adhesive characteristic control layer may be formed of a material having rigidity that varies depending on a change in a temperature, light intensity, or humidity.

In some embodiments, the speed-dependent adhesive characteristic control layer may be formed to have rigidity that varies depending on regions.

In some embodiments, the speed-dependent adhesive characteristic control layer may be formed to be tensile-transformed in a thickness direction due to a cut pattern.

In some embodiments, the speed-dependent adhesive characteristic control layer may be formed to be partially arranged in the support layer.

In some embodiments, the speed-dependent adhesive characteristic control layer may be formed of a porous material.

Also, the above purpose may be achieved by a transfer film for a high-speed transfer process, including a first adhesive layer formed of a viscoelastic material so that a device is adhered thereto, and a support layer supporting the first adhesive layer, wherein the support layer is formed of a material having rigidity that varies depending on external physical conditions, and when a placing process is performed after performing a picking process, the placing process is performed after a rigidity of the support layer is weakened.

Also, the above purpose may be achieved by a transfer method using a transfer film, including, in a transfer process, in which a device is transferred onto a target substrate by using the transfer film that is formed of a viscoelastic material so as to adhere the device thereto, bringing the transfer film on which the device is adhered into contact with the target substrate and pressing the transfer film, changing a characteristic that an adhesive force of the first adhesive layer changes according to a placing speed of the transfer film with respect to the transfer film, and performing a placing process.

In some embodiments, the transfer film may include the first adhesive layer, a support layer supporting the first adhesive layer, a second adhesive layer formed of a viscoelastic material so that the support layer is adhered thereto, and a rigidity reinforcement layer reinforcing a rigidity of the transfer film and supporting the second adhesive layer, changing of the characteristic that the adhesive force of the first adhesive layer changes according to a placing speed of the transfer film with respect to the transfer film comprises weakening a rigidity of the transfer film by removing the rigidity reinforcement layer.

In some embodiments, the transfer film may include the first adhesive layer, and a support layer that supports the first adhesive layer, the support layer is formed of a material having rigidity that varies depending on external physical conditions, and changing of the characteristic that the adhesive force of the first adhesive layer changes according to a placing speed of the transfer film with respect to the transfer film comprises weakening a rigidity of the support layer by changing external physical environment.

### MODE FOR THE INVENTION

Details of embodiments are included in the following description and the accompanying drawings.

The attached drawings illustrate one or more embodiments and are referred to in order to gain a sufficient understanding, the merits thereof, and the objectives accomplished by the implementation. However, the present disclosure is not limited to the exemplary embodiments set forth below, and may be embodied in various other forms. The embodiments are for rendering the description of the present disclosure complete and are set forth to provide a complete understanding of the scope of the disclosure to one of ordinary skill in the art to which the present disclosure pertains. Throughout the specification, like reference numerals denote the same elements.

Hereinafter, the present disclosure is described with reference to the drawings for illustrating a transfer film for high-speed transfer process and a transfer method using the transfer film according to embodiments of the present disclosure.

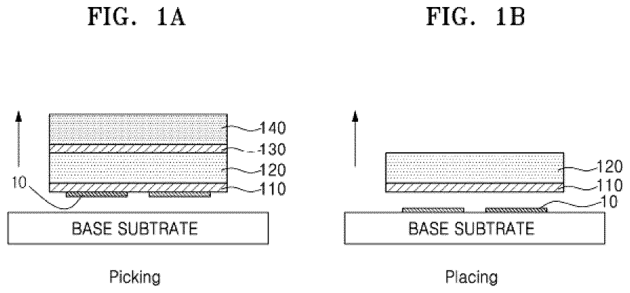

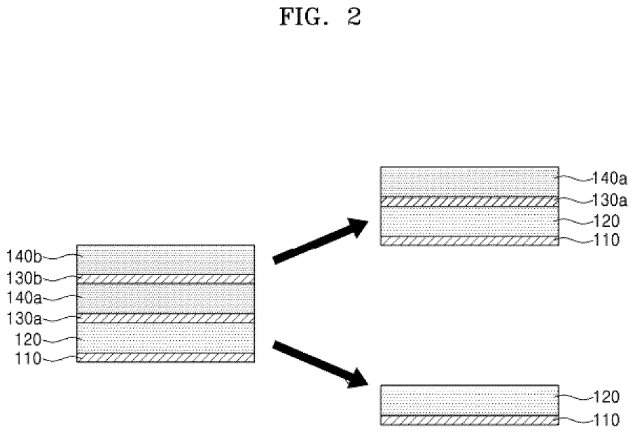

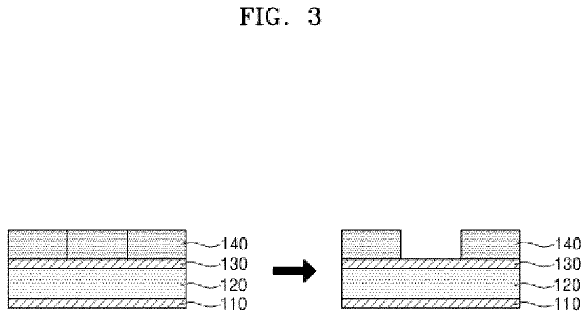

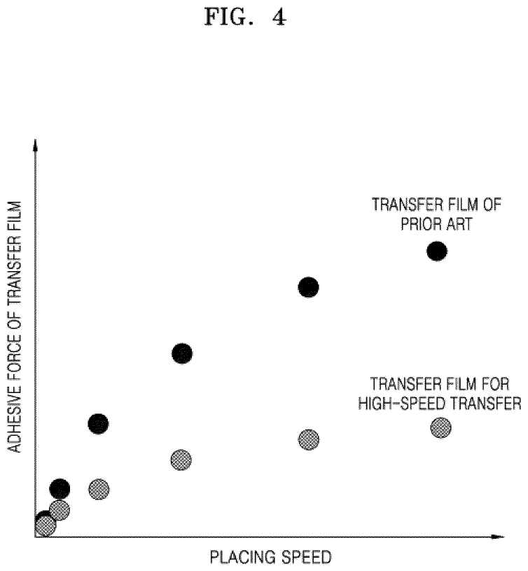

FIG. 1A and FIG. 1B illustrate a transfer film for high-speed transfer process, according to an embodiment of the present disclosure, FIG. 2 shows a modified example of FIG. 1A and FIG. 1B, and FIG. 3 shows another modified example of FIG. 1A and FIG. 1B, and FIG. 4 is a graph showing a variation in an adhesive force according to a placing speed, in the transfer film for high-speed transfer process according to the present disclosure and a transfer film according to the prior art.

A transfer film for high-speed transfer process according to an embodiment of the present disclosure may include a first adhesive layer 110, a support layer 120, a second adhesive layer 130, and a rigidity reinforcement layer 140.

The first adhesive layer 110 is formed of a viscoelastic material, so as to move a device 10 arranged on a base substrate to the transfer film via an adhesive force of the first adhesive layer 110 in a picking process and to move the device 10 attached to the first adhesive layer 110 to a target substrate and arrange the device in a placing process.

The support layer 120 is a base film supporting the first adhesive layer 110.

A transfer film according to the prior art only includes the support layer 120 and the first adhesive layer 110, but the transfer film for high-speed transfer process according to the present disclosure may further include the second adhesive layer 130 and the rigidity reinforcement layer 140.

The second adhesive layer 130 may be also formed of a viscoelastic material and adheres on the other surface of the support layer 120, which is opposite to the surface where the first adhesive layer 110 is formed. In some embodiments, the adhesive force of the second adhesive layer 130 may be less than that of the first adhesive layer 110.

The rigidity reinforcement layer 140 is a layer for reinforcing the rigidity of the transfer film and supports the second adhesive layer 130. In some embodiments, the rigidity reinforcement layer 140 may be formed of a material having a rigidity greater than that of the support layer 120.

In some embodiments, in the picking process, when detaching the transfer film after pressing the device 10 arranged on the base substrate by using the transfer film for high-speed transfer process, which includes the first adhesive layer 110, the support layer 120, the second adhesive layer 130, and the rigidity reinforcement layer 140, the device 10 may be moved to the transfer film due to the adhesive force of the first adhesive layer 110. As shown in FIG. 4, the adhesive layer formed of the viscoelastic material has a speed-dependent adhesive characteristic, that is, the adhesive force increases when a speed of detaching the transfer film (placing speed) increases. Therefore, because the device 10 arranged on a base substrate is transferred to the transfer film due to the adhesive force of the first adhesive layer 110 in the picking process, the adhesive force increases as the speed of detaching the transfer film increases after attaching and pressing the transfer film onto the base substrate, and then, the device 10 may be more effectively transferred from the base substrate to the transfer film.

In some embodiments, in the picking process, the adhesive force increases as the rigidity of the transfer film increases, and thus, the device 10 may be more effectively moved from the base substrate to the transfer film. In the present disclosure, the rigidity of the transfer film may be improved by the rigidity reinforcement layer 140.

Next, in the placing process, the rigidity reinforcement layer 140 is removed. That is, after attaching and pressing the transfer film onto a target substrate, the rigidity reinforcement layer 140 is removed, and then, the support layer 120 is detached from the target substrate, that is, the placing process is performed. In some embodiments, because the adhesive force of the second adhesive layer 130 is less than that of the first adhesive layer 110, the rigidity reinforcement layer 140 may be only detached from the target substrate without detaching the support layer 120 from the target substrate when detaching the rigidity reinforcement layer 140 from the support layer 120.

As a reference, in the present specification, performing of the placing process may specifically denote a process of detaching the transfer film from the target substrate.

When the rigidity of the transfer film is weakened, the speed-dependent adhesive characteristic in which the adhesive force of the adhesive layer increased when the speed of detaching the transfer film becomes faster may be weakened. That is, as shown in FIG. 4, the transfer film according to the present disclosure may have a less increase in the adhesive force than that of the prior art, even when the speed of detaching the transfer film increases.

As described above, during performing the picking process, higher rigidity of the transfer film is desirable, while during the placing process, lower rigidity of the transfer film is desirable. Accordingly, in the present disclosure, the transfer film is formed in a multi-layered structure having the support layer 120 and the rigidity reinforcement layer 140, and the rigidity reinforcement layer 140 is removed when performing the placing process so as to weaken the rigidity of the transfer film, and then, the transfer process may be performed, thereby increasing the transfer yield.

In some embodiments, the rigidity of the entire transfer film including the rigidity reinforcement layer 140 is formed to be greater than or equal to that of the transfer film according to the prior art, and the rigidity of the transfer film (support layer 120) from which the rigidity reinforcement layer 140 is removed may be formed to be weaker than that of the transfer film according to the prior art.

FIG. 2 shows a modified example of the embodiment shown in FIG. 1A and FIG. 1B. The s tructures of the first adhesive layer 110 and the support layer 120 are the same as those of FIG. 1A and FIG. 1B, and in the present embodiment, rigidity reinforcement layers 140a and 140b are provided in multi-layers including second adhesive layers 130a and 130b. That is, the rigidity reinforcement layer 140 may be formed in multi-layers including a first rigidity reinforcement layer 140a and a second rigidity reinforcement layer 140b with the adhesive layer 130b arranged therebetween.

Therefore, the rigidity reinforcement layer 140 having the multi-layers may be selectively removed, and accordingly, the speed-dependent adhesive characteristic of the first adhesive layer 110 may be controlled when performing the placing process. For example, when performing the placing process, the rigidity of the transfer film may be controlled to be different in the case in which the second rigidity reinforcement layer 140b is only removed and in the case in which the second rigidity reinforcement layer 140b and the first rigidity reinforcement layer 140a are removed along with each other, and thus, the speed-dependent adhesive characteristic of the first adhesive layer 110 may be differently controlled.

In some embodiments, as shown in FIG. 3, the rigidity reinforcement layer 140 may be formed to be partially removable. The rigidity reinforcement layer 140 is partially removed during the placing process, so that the region from which the rigidity reinforcement layer 140 is removed has a weakened rigidity and the speed-dependent adhesive characteristic of the first adhesive layer 110 is weakened. In addition, the region where the rigidity reinforcement layer 140 remains has the speed-dependent adhesive characteristic maintained constantly. Thus, selective transfer for each region may be possible when performing the placing process at a certain speed. That is, the device 10 located on the region where the rigidity reinforcement layer 140 is removed is transferred onto the target substrate, and the device 10 located on the region where the rigidity reinforcement layer 140 remains may not be transferred onto the target substrate.

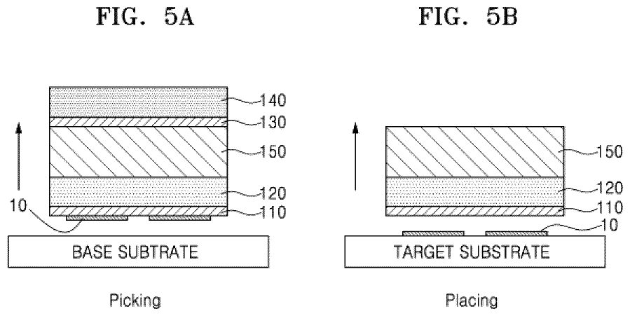

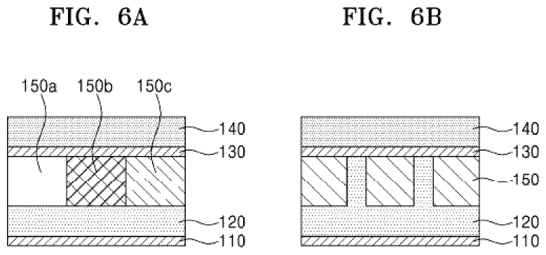

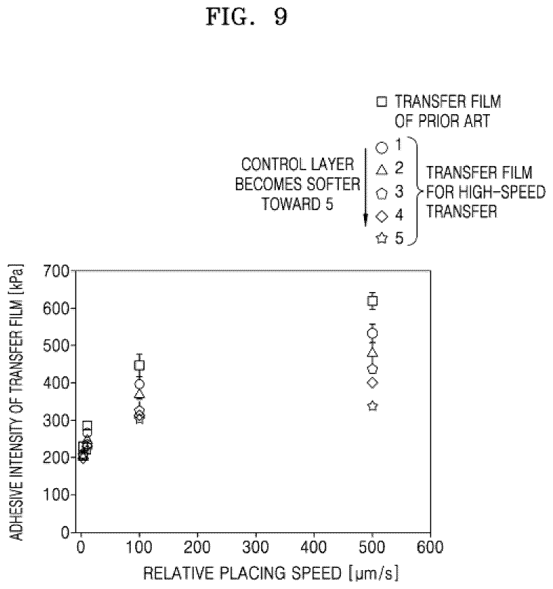

FIG. 5A and FIG. 5B show a transfer film for high-speed transfer process, according to another embodiment of the present disclosure, FIGS. 6 to 8 show modified examples of FIG. 5A and FIG. 5B, and FIG. 9 shows results of measuring the adhesive force depending on the placing speed, according to the rigidity of a speed-dependent adhesive characteristic control layer in FIG. 5A and FIG. 5B.

A transfer film for high-speed transfer process, according to another embodiment of the present disclosure, may include the first adhesive layer 110, the support layer 120, a speed-dependent adhesive characteristic control layer 150, the second adhesive layer 130, and the rigidity reinforcement layer 140.

The first adhesive layer 110, the support layer 120, the second adhesive layer 130, and the rigidity reinforcement layer 140 are the same as those described above with reference to FIG. 1A and FIG. 1B. The speed-dependent adhesive characteristic control layer 150 is formed on the other surface of the support layer 120, opposite to the surface where the first adhesive layer 110 is formed. That is, the speed-dependent adhesive characteristic control layer 150 may be formed between the support layer 120 and the second adhesive layer 130. The speed-dependent adhesive characteristic control layer 150 controls the speed-dependent adhesive characteristic of the first adhesive layer 110 when performing the placing process. That is, when the speed-dependent adhesive characteristic control layer 150 is formed on the rear surface of the support layer 120 as shown in FIG. 5A and FIG. 5B as compared with the case in which the support layer 120 is only formed as shown in FIG. 1A and FIG. 1B while performing the placing process, the characteristic that the adhesive force of the first adhesive layer 110 increases when the placing speed increases may be controlled to be reduced.

The speed-dependent adhesive characteristic control layer 150 may be formed of a material having a rigidity less than that of the support layer 120. For example, a soft polymer, e.g., a polydimethylsiloxane (PDMS) polymer, may be used.

FIG. 9 shows results of experiments in which a variation in the adhesive force of the transfer film according to the placing speed was tested, in the case of the transfer film only including the support layer 120 according to the prior art and in the case of the transfer film having the speed-dependent adhesive characteristic control layer 150 of a soft material formed on one side of the support layer 120.

When the speed-dependent adhesive characteristic control layer 150 is formed, a degree of increasing the adhesive force when the placing speed increases is decreased. In some embodiments, as the speed-dependent adhesive characteristic control layer 150 is formed of a soft material, the speed-dependent adhesive characteristic of the transfer film is further weakened.

In some embodiments, the speed-dependent adhesive characteristic control layer 150 may be formed of a material having the rigidity varying depending on external physical changes. For example, the material may have the rigidity that varies depending on the variation in the external temperature, light intensity, or humidity. In some embodiments, before performing the placing process, the rigidity of the speed-dependent adhesive characteristic control layer 150 may be weakened by changing the external physical conditions such as temperature, light intensity, or humidity, so as to control the speed-dependent adhesive characteristic of the first adhesive layer 110.

In some embodiments, as shown in FIG. 6A, speed-dependent adhesive characteristic control layers 150a, 150b, and 150c may be formed of materials having different rigidities according to regions. Therefore, the adhesive force of the first adhesive layer 110 may be differently controlled according to respective regions with respect to the same placing speed.

In FIG. 6B, the speed-dependent adhesive characteristic control layer 150 is formed differently according to the regions, and the speed-dependent adhesive characteristic control layer 150 may be formed to be partially arranged on one side of the support layer 120. In the region of the speed-dependent adhesive characteristic control layer 150, where a soft material is formed as compared with the support layer 120, a high-speed transfer may be performed, and in the region where the support layer 120 is only formed, it may be relatively difficult to perform the high-speed transfer.

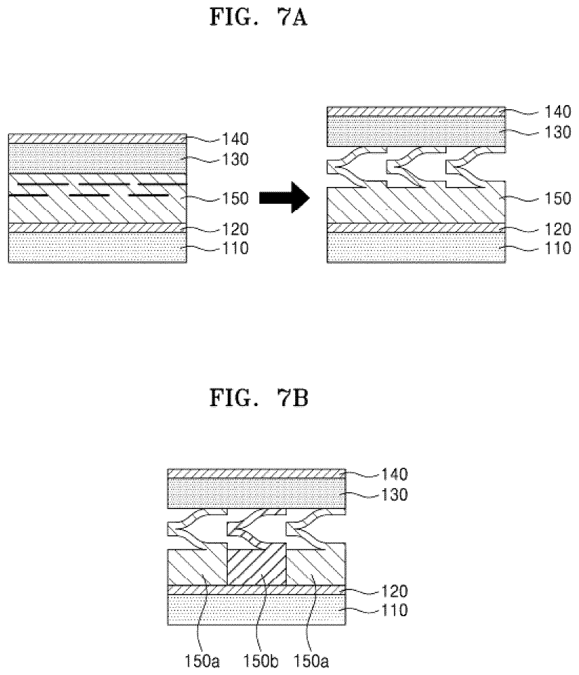

In addition, as shown in FIG. 7A, the speed-dependent adhesive characteristic control layer 150 may be formed as a structure that is tensile-transformed in the thickness direction due to a cut pattern. In some embodiments, the speed-dependent adhesive characteristic control layer 150 may be tensile-transformed when removing the rigidity reinforcement layer 140, or after removing the rigidity reinforcement layer 140, additional external force of pulling the speed-dependent adhesive characteristic control layer 150 upward may be applied to tensile-transform the speed-dependent adhesive characteristic control layer. Because the speed-dependent adhesive characteristic control layer 150 is tensile-transformed, the rigidity of the transfer film may be weakened, and in the placing process, the speed-dependent adhesive characteristic of the first adhesive layer 110 may be controlled.

As shown in FIG. 7B, the speed-dependent adhesive characteristic control layer 150 is formed of a structure that is tensile-transformed in the thickness direction due to the cut pattern, but may be partially formed of materials having different rigidities as shown in FIG. 6A and FIG. 6B. Thus, the speed-dependent adhesive characteristic of the first adhesive layer 110 may be differently controlled according to the regions.

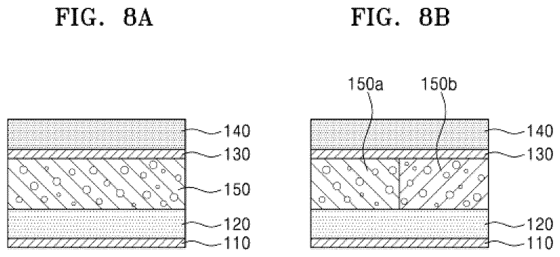

In some embodiments, as shown in FIG. 8A, the speed-dependent adhesive characteristic control layer 150 may be formed of a porous material and control the speed-dependent adhesive characteristic of the first adhesive layer 110.

As shown in FIG. 8B, the speed-dependent adhesive characteristic control layer 150 may be formed of a porous material, and may be partially formed of materials having different rigidities as shown in FIG. 6A and FIG. 6B. Thus, the speed-dependent adhesive characteristic of the first adhesive layer 110 may be differently controlled according to the regions.

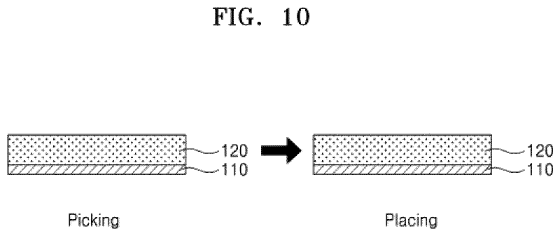

FIG. 10 is a diagram showing a transfer film for high-speed transfer process, according to another embodiment of the present disclosure.

The transfer film for high-speed transfer process, according to another embodiment of the present disclosure, may include the first adhesive layer 110 and the support layer 120.

As described above, the first adhesive layer 110 is formed of a viscoelastic material, so as to move the device 10 arranged on a base substrate to the transfer film via an adhesive force of the first adhesive layer 110 in a picking process and to move the device 10 attached to the first adhesive layer 110 to a target substrate and arranged in a placing process.

The support layer 120 is a base film supporting the first adhesive layer 110. In the embodiment, the support layer 120 may be formed of a material having rigidity that varies depending on external physical changes. For example, the material may have the rigidity that varies depending on the variation in the external temperature, light intensity, and humidity.

In some embodiments, when performing the picking process, the rigidity of the support layer 120 may be increased due to the external physical conditions. In some embodiments, when performing the placing process, the external physical conditions are changed to weaken the rigidity of the support layer 120, and then, the speed-dependent adhesive characteristic of the first adhesive layer 110 may be controlled.

A transfer method using the transfer film, according to an embodiment of the present disclosure, may be performed by using the transfer film for high-speed transfer process, described above with reference to FIGS. 1 to 9.

As described with reference to FIG. 1A and FIG. 1B, when the picking process is performed, the transfer film is pressed onto a base substrate, and after that, the transfer film is detached from the base substrate so as to move the device 10 arranged on the base substrate onto the transfer film by the adhesive force of the first adhesive layer 110. In this case, the adhesive force of the first adhesive layer 110 increases as the speed of detaching the transfer film from the base substrate increases, and then, the device 10 may be effectively moved from the base substrate to the transfer film.

Next, after performing the picking process, the transfer film to which the device 10 is adhered is brought into contact with the target substrate and then pressed.

Next, the speed-dependent adhesive characteristic of the transfer film is changed. As shown in FIG. 1A and FIG. 1B, when the transfer film is formed to have the multi-layered structure including the support layer 120 and the rigidity reinforcement layer 140, the rigidity reinforcement layer 140 having a strong rigidity is removed to weaken the rigidity of the transfer film and the speed-dependent adhesive characteristic of the transfer film may be changed.

In some embodiments, as described above with reference to FIGS. 5 to 8, by providing the speed-dependent adhesive characteristic control layer 150 on one surface of the support layer 120, the speed-dependent adhesive characteristic that the adhesive force of the transfer film increases as the placing speed increases may be more effectively reduced.

In some embodiments, as described above with reference to FIG. 10, when the support layer 120 is formed of the material having the rigidity that varies depending on the physical change on the outside, the speed-dependent adhesive characteristic may be controlled by changing the external physical conditions such as temperature, light intensity, or humidity so that the rigidity of the support layer 120 increases during performing the picking process, and by changing the external physical conditions so that the rigidity of the support layer 120 is weakened during performing the placing process.

It is to be understood that the present disclosure is not limited to the disclosed embodiments, but, on the contrary, may be embodied in various embodiments. Various modifications may be made to the disclosure by one of skilled in the art without departing from the spirit and scope of the disclosure as defined in the appended claims.

1. A transfer film for a high-speed transfer process, the transfer film comprising:
a first adhesive layer formed of a viscoelastic material so that a device is adhered thereto;
a support layer supporting the first adhesive layer;
a second adhesive layer formed of a viscoelastic material so that the support layer is adhered thereto; and
a rigidity reinforcement layer reinforcing a rigidity of the transfer film and supporting the second adhesive layer,
wherein, when a placing process is performed after performing a picking process, the placing process is performed after the rigidity reinforcement layer is removed so as to weaken the rigidity of the transfer film.

2. The transfer film of claim 1, wherein
the rigidity reinforcement layer is formed in multi-layers.

3. The transfer film of claim 1, wherein
the rigidity reinforcement layer is formed of a material having a rigidity greater than a rigidity of the support layer.

4. The transfer film of claim 1, wherein
the rigidity reinforcement layer is partially removable.

5. The transfer film of claim 1, further comprising
a speed-dependent adhesive characteristic control layer which is formed above one surface of the support layer, which faces the second adhesive layer of the support layer, and controls a characteristic that an adhesive force of the first adhesive layer changes according to a placing speed.

6. The transfer film of claim 5, wherein
the speed-dependent adhesive characteristic control layer is formed of a material having a rigidity less than the rigidity of the support layer.

7. The transfer film of claim 5, wherein
the speed-dependent adhesive characteristic control layer is formed of a material having rigidity that varies depending on external physical changes.

8. The transfer film of claim 7, wherein
the speed-dependent adhesive characteristic control layer is formed of a material having rigidity that varies depending on a change in a temperature, light intensity, or humidity.

9. The transfer film of claim 5, wherein
the speed-dependent adhesive characteristic control layer is formed to have rigidity that varies depending on regions.

10. The transfer film of claim 5, wherein
the speed-dependent adhesive characteristic control layer is formed to be tensile-transformed in a thickness direction due to a cut pattern.

11. The transfer film of claim 5, wherein
the speed-dependent adhesive characteristic control layer is formed to be partially arranged in the support layer.

12. The transfer film of claim 5, wherein
the speed-dependent adhesive characteristic control layer is formed of a porous material.

13. A transfer film for a high-speed transfer process, the transfer film comprising:
a first adhesive layer formed of a viscoelastic material so that a device is adhered thereto; and
a support layer supporting the first adhesive layer,
wherein the support layer is formed of a material having rigidity that varies depending on external physical conditions, and
when a placing process is performed after performing a picking process,
the placing process is performed after a rigidity of the support layer is weakened.

14. A transfer method using a transfer film, the transfer method comprising:
in a transfer process, in which a device is transferred onto a target substrate by using the transfer film that is formed of a viscoelastic material so as to adhere the device thereto,
bringing the transfer film on which the device is adhered into contact with the target substrate and pressing the transfer film;
changing a characteristic that an adhesive force of the first adhesive layer changes according to a placing speed of the transfer film with respect to the transfer film; and
performing a placing process.

15. The transfer method of claim 14, wherein
the transfer film comprises:
the first adhesive layer;
a support layer supporting the first adhesive layer;
a second adhesive layer formed of a viscoelastic material so that the support layer is adhered thereto; and
a rigidity reinforcement layer reinforcing a rigidity of the transfer film and supporting the second adhesive layer,
changing of the characteristic that the adhesive force of the first adhesive layer changes according to a placing speed of the transfer film with respect to the transfer film comprises weakening a rigidity of the transfer film by removing the rigidity reinforcement layer.

16. The transfer method of claim 14, wherein
the transfer film comprises:
the first adhesive layer; and
a support layer that supports the first adhesive layer,
the support layer is formed of a material having rigidity that varies depending on external physical conditions, and
changing of the characteristic that the adhesive force of the first adhesive layer changes according to a placing speed of the transfer film with respect to the transfer film comprises weakening a rigidity of the support layer by changing external physical environment.
